(19) United States
(12) Patent Application Publication
(10) Pub. No.: US 2025/0022992 A1
(43) Pub. Date: Jan. 16, 2025

(54) DISPLAY DEVICE AND MANUFACTURING METHOD THEREOF

(71) Applicant: Samsung Display Co., LTD., Yongin-si (KR)

(72) Inventor: Ki Su JIN, Yongin-si (KR)

(21) Appl. No.: 18/416,179

(22) Filed: Jan. 18, 2024

(30) Foreign Application Priority Data
Jul. 13, 2023 (KR) 10-2023-0091133

(51) Int. Cl. H01L 33/54; H01L 25/16

(52) U.S. Cl. CPC H01L 33/54; H01L 25/167; H01L 2933/005

(57) ABSTRACT

A display device includes an active area and a peripheral area adjacent to the active area, the display device including: a base layer; and a backplane structure including a backplane layer on the base layer, an outer via layer on the backplane layer, and an outer protective layer on the outer via layer, wherein the outer protective layer includes a first outer protective layer having holes exposing the outer via layer in the active area, and a second outer protective layer having a plurality of trenches recessed toward the outer via layer without exposing the outer via layer in the peripheral area.

### CROSS-REFERENCE TO RELATED APPLICATION

The present application claims priority to and the benefit of Korean Patent Application No. 10-2023-0091133, filed on Jul. 13, 2023, in the Korean Intellectual Property Office, the entire disclosure of which is hereby incorporated herein by reference.

### BACKGROUND

### 1. Field

Aspects of some embodiments of the present disclosure relate to a display device and a manufacturing method thereof.

### 2, Brief Description of the Related Art

In recent years, as interest in information displays has increased, research and development on display devices have been continuously conducted.

The above information disclosed in this Background section is only for enhancement of understanding of the background and therefore the information discussed in this Background section does not necessarily constitute prior art.

### SUMMARY

Aspects of some embodiments of the present invention include a display device that can be manufactured with relatively improved reliability and a manufacturing method thereof.

According to some embodiments of the present invention, a display device includes an active area and a peripheral area adjacent to the active area, according to embodiments of the present invention may include a base layer; and a backplane structure including a backplane layer on the base layer, an outer via layer on the backplane layer, and an outer protective layer on the outer via layer. According to some embodiments, the outer protective layer may include a first outer protective layer having holes exposing the outer via layer in the active area, and a second outer protective layer having a plurality of trenches recessed toward the outer via layer without exposing the outer via layer in the peripheral area.

According to some embodiments, the second outer protective layer may overlap the peripheral area and the active area.

According to some embodiments, the peripheral area may be formed along an edge of the active area.

According to some embodiments, each of the plurality of trenches may surround at least a portion of the active area.

According to some embodiments, the active area may extend in a first direction and a second direction crossing the first direction, and each of the plurality of trenches may include a first slit extending in the first direction, a second slit extending in the second direction, and a third slit connecting the first and second slits and having an “L” shape.

According to some embodiments, the active area may extend in a first direction and a second direction crossing the first direction, and each of the plurality of trenches may include first grooves arranged in the first direction and second grooves arranged in the second direction crossing the first direction.

According to some embodiments, the backplane structure may include a first backplane structure. According to some embodiments, the display device may further include a second backplane structure on the base layer and including a second backplane layer, a lower via layer on the second backplane layer, and a lower protective layer on the lower via layer. According to some embodiments, the base layer may be between the first backplane structure and the second backplane structure, and the lower protective layer may include a first lower protective layer having holes exposing the lower via layer in the active area, and a second lower protective layer including trenches recessed toward the lower via layer without exposing the lower via layer in the peripheral area.

According to some embodiments, the outer protective layer and the lower protective layer may include an inorganic material, and the outer via layer and the lower via layer may include an organic material.

According to some embodiments of the present disclosure, in a manufacturing method of a display device, the method includes manufacturing cells each including a backplane structure, each of the cells having an active area and a peripheral area adjacent to the active area; forming a support layer in the peripheral area on a backplane layer; forming an ink layer overlapping the active area and contacting the support layer on the backplane layer; removing the support layer; and separating the cells. According to some embodiments, the backplane structure may include an outer via layer. According to some embodiments, the manufacturing the cells may include forming a first outer protective layer on the outer via layer in the active area and having holes exposing the outer via layer; and forming a second outer protective layer on the outer via layer in the peripheral area and having a plurality of trenches recessed toward the outer via layer without exposing the outer via layer.

According to some embodiments, the forming the second outer protective layer may include forming the plurality of trenches using a halftone mask.

According to some embodiments, the peripheral area may be formed along an edge of the active area, and the second outer protective layer may overlap the peripheral area and the active area.

According to some embodiments, the support layer may include protrusions directly on the second outer protective layer and protruding toward the outer via layer to fill the trenches.

According to some embodiments, a height of the ink layer from an upper surface of the first outer protective layer may be lower than a height of the support layer from an upper surface of the second outer protective layer.

According to some embodiments, the removing the support layer may include arranging a fixing member to overlap the ink layer so that the ink layer is not separated from the first outer protective layer.

### BRIEF DESCRIPTION OF THE DRAWINGS

The accompanying drawings, which are included to provide a further understanding of embodiments according to the present disclosure, and are incorporated in and constitute a part of this specification, illustrate aspects of some embodiments of the present disclosure, and, together with the description, serve to explain aspects of some embodiments of the present disclosure.

FIG. 1 is a plan view illustrating a display device according to some embodiments.

FIG. 2 is a plan view illustrating one of pixels of FIG. 1.

FIG. 3 is a cross-sectional view illustrating a cross section of a pixel taken along the line C-C′ of FIG. 2 according to some embodiments.

FIG. 4 is a cross-sectional view of a portion of a first backplane layer of FIG. 3 according to some embodiments.

FIG. 5 is a cross-sectional view taken along the line A-A′ of FIG. 1.

FIG. 6 is a cross-sectional view taken along the line B-B′ of FIG. 1.

FIG. 7 is a flowchart illustrating a manufacturing method of a display device according to some embodiments of the present invention.

FIG. 8 is a plan view illustrating cells in operation S710 of FIG. 7 according to some embodiments.

FIG. 9 is a cross-sectional view taken along the line I-I′ of FIG. 8 according to some embodiments.

FIG. 10 is a cross-sectional view taken along the line I-l′ of FIG. 8 in operation S720 of FIG. 7 according to some embodiments.

FIG. 11 is a plan view illustrating cells in operation S720 of FIG. 7 according to some embodiments.

FIG. 12 is a flowchart illustrating a manufacturing method of a display device according to some embodiments of the present invention.

FIG. 13 is a plan view illustrating cells in operation S1210 of FIG. 12 according to some embodiments.

FIGS. 14 and 15 are cross-sectional views taken along the line II-II′ of FIG. 13 to explain a manufacturing method of operation S1210 of FIG. 12 according to some embodiments.

FIG. 16 is a cross-sectional view taken along the line II-II′ of FIG. 13 in operation S1230 of FIG. 12 according to some embodiments.

FIG. 17 is a cross-sectional view taken along the line II-II′ of FIG. 13 in operation S1250 of FIG. 12 according to some embodiments.

FIG. 18 is a cross-sectional view of the display device taken along the line II-II′ of FIG. 13 after an ink layer is removed in operation S1260 of FIG. 12 according to some embodiments.

FIG. 19 is a plan view illustrating trenches in an area A1 of FIG. 13 according to some embodiments.

FIG. 20 is a plan view illustrating trenches in the area A1 of FIG. 13 according to some embodiments.

FIG. 21 is a block diagram illustrating an electronic device according to some embodiments of the present invention.

### DETAILED DESCRIPTION

Hereinafter, aspects of some embodiments according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiments described herein. However, the embodiments described herein are provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

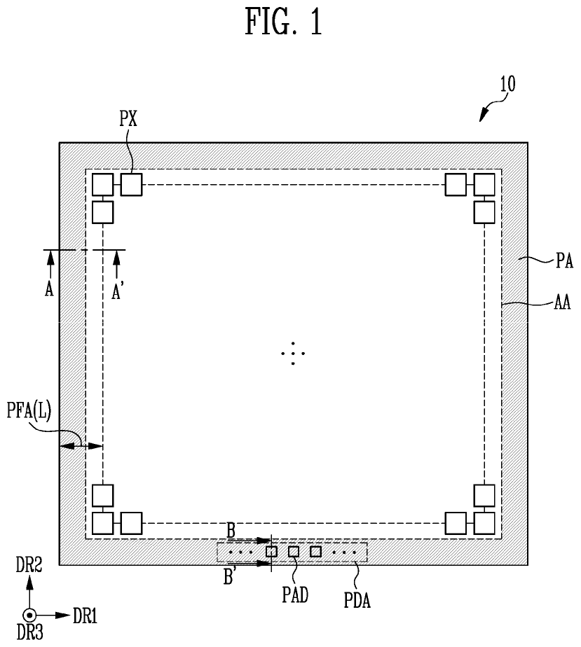

FIG. 1 is a plan view illustrating a display device according to some embodiments.

Referring to FIG. 1, a display device 10 may be configured to output light information. For example, the display device 10 may be a device that displays a moving image or a still image. The display device 10 may be used as a display screen of various products such as televisions, laptops, monitors, billboards, or Internet of Things (IOTs), as well as portable electronic devices such as mobile phones, smart phones, tablet personal computers, smart watches, watch phones, mobile communication terminals, electronic notebooks, e-books, portable multimedia players (PMPs), navigations, or ultra mobile PCs (UMPCs). However, the application field of the display device 10 is not limited to a specific example.

The display device 10 may be formed of a rectangular flat plate having a long side in a first direction DR1 and a short side in a second direction DR2 crossing the first direction DR1. A corner portion where the long side of the first direction DR1 and the short side of the second direction DR2 meet may be formed round to have a curvature (e.g., a set or predetermined curvature) or formed at a right angle. The planar shape of the display device 10 is not limited to a quadrangle, and may be formed in a polygonal, circular or elliptical shape. The display device 10 may be formed flat, but is not limited thereto. For example, the display device 10 may include curved portions formed at left and right ends and having a constant curvature or a changing curvature. In addition, the display device 10 may be formed to be flexible so as to be bent, folded, or rolled.

The display device 10 may include an active area AA and a peripheral area PA. The display device 10 may include a peripheral cover area PFA. The display device 10 may include a pad area PDA.

The active area AA may be an area where a pixel PX is located. The active area AA may be a display area. The active area AA may be an area where a light emitting element LE is located. For example, the active area AA may overlap the pixel PX (or the light emitting element LE) when viewed on a plane.

The peripheral area PA may include an area other than the active area AA. The peripheral area PA may be an area in which the pixel PX is not located. A wiring and a pad PAD electrically connected to the pixel PX may be located in the peripheral area PA. The peripheral area PA may be a non-display area. The peripheral area PA may include a pad area PDA where the pad PAD is located.

The display device 10 may include the pad PAD located in the pad area PDA. The pad PAD may be located on one side of the active area AA. However, the present disclosure is not particularly limited.

The peripheral cover area PFA may include a portion of the peripheral area PA. The peripheral cover area PFA may be formed on an outer periphery of the display device 10. The peripheral cover area PFA may have a width equal to a cover length L from an edge of the display device 10. The peripheral cover area PFA may overlap the pad area PDA. According to some embodiments, the cover length L may be 800 μm or less. For example, the cover length L may be 100 μm or more and 800 μm or less. In another example, the cover length L may be 500 μm or less. However, the present disclosure is not necessarily limited thereto.

The peripheral cover area PFA may include a portion of the active area AA. For example, the peripheral cover area PFA may overlap the pixel PX when viewed on a plane. The peripheral cover area PFA may overlap the light emitting element LE when viewed on a plane.

The peripheral cover area PFA may be formed along the edge of the display device 10. The peripheral cover area PFA may overlap the outermost edge of the display device 10.

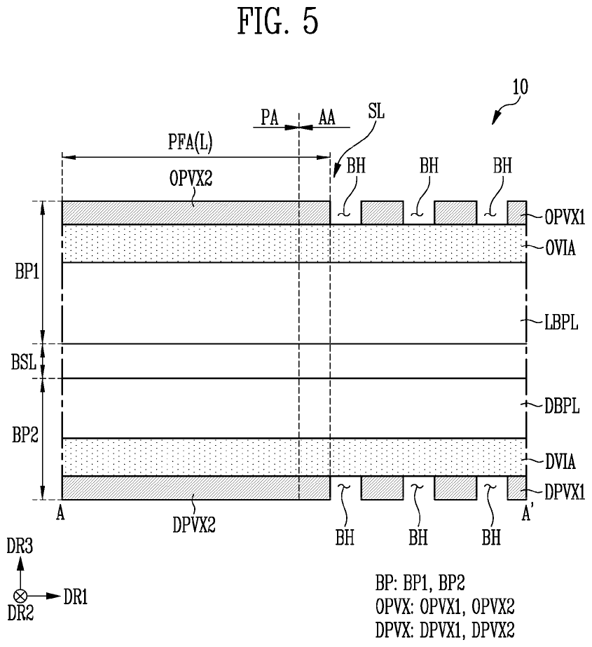

The peripheral cover area PFA may be an area where a second outer protective layer OPVX2 (refer to FIG. 5) covering the entire peripheral area PA is located. Further details regarding this will be described later.

The display device 10 may further include pixels PX, scan lines extending in the first direction DR1, and data lines extending in the second direction DR2 to display an image. The pixels PX may be arranged in a matrix form in the first and second directions DR1 and DR2.

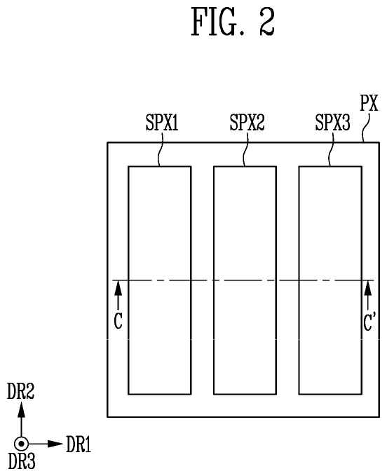

FIG. 2 is a plan view illustrating one of pixels of FIG. 1.

Referring to FIG. 2, the pixel PX may include a plurality of sub-pixels SPX1, SPX2, and SPX3. FIG. 2 shows a case in which the pixel PX includes three sub-pixels SPX1, SPX2, and SPX3, that is, a first sub-pixel SPX1, a second sub-pixel SPX2, and a third sub-pixel SPX3 as an example, but embodiments of the present disclosure are not limited thereto.

The first sub-pixel SPX1, the second sub-pixel SPX2, and the third sub-pixel SPX3 may be connected to one data line among the data lines and at least one scan line among the scan lines.

Each of the first sub-pixel SPX1, the second sub-pixel SPX2, and the third sub-pixel SPX3 may have a rectangular, square, or rhombus planar shape. For example, each of the first sub-pixel SPX1, the second sub-pixel SPX2, and the third sub-pixel SPX3 may have a rectangular planar shape having a short side in the first direction DR1 and a long side in the second direction DR2 as shown in FIG. 2. Alternatively, according to some embodiments, each of the first sub-pixel SPX1, the second sub-pixel SPX2, and the third sub-pixel SPX3 may have a square or rhombus planar shape including sides having the same length in the first direction DR1 and the second direction DR2.

The first sub-pixel SPX1, the second sub-pixel SPX2, and the third sub-pixel SPX3 may be arranged in the first direction DR1. Alternatively, one of the second sub-pixel SPX2 and the third sub-pixel SPX3 and the first sub-pixel SPX1 may be arranged in the first direction DR1, and the other one and the first sub-pixel SPX1 may be arranged in the second direction DR2.

Alternatively, one of the first sub-pixel SPX1 and the third sub-pixel SPX3 and the second sub-pixel SPX2 may be arranged in the first direction DR1, and the other one and the second sub-pixel SPX2 may be arranged in the second direction DR2. Alternatively, one of the first sub-pixel SPX1 and the second sub-pixel SPX2 and the third sub-pixel SPX3 may be arranged in the first direction DR1, and the other one and the third sub-pixel SPX3 may be arranged in the second direction DR2.

The first sub-pixel SPX1 may emit first light, the second sub-pixel SPX2 may emit second light, and the third sub-pixel SPX3 may emit third light. Here, the first light may be light in a red wavelength band, the second light may be light in a green wavelength band, and the third light may be light in a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but embodiments of the present disclosure are not limited thereto.

Each of the first sub-pixel SPX1, the second sub-pixel SPX2, and the third sub-pixel SPX3 may include the light emitting element LE configured to emit light.

The light emitting element LE may be provided in various forms. For example, the light emitting element LE may be an inorganic light emitting element including an inorganic material. According to some embodiments, the light emitting element LE may be an organic light emitting diode (OLED). However, the present disclosure is not limited to a specific example. Hereinafter, for convenience of description, embodiments in which the light emitting element LE is an inorganic light emitting element including an inorganic semiconductor and is a flip chip type micro LED (Light Emitting Diode) will be described as an example.

As shown in FIG. 2, an area of the first sub-pixel SPX1, an area of the second sub-pixel SPX2, and an area of the third sub-pixel SPX3 may be substantially the same, but embodiments of the present disclosure are limited thereto. At least one of the area of the first sub-pixel SPX1, the area of the second sub-pixel SPX2, and the area of the third sub-pixel SPX3 may be different from the other one. Alternatively, two of the area of the first sub-pixel SPX1, the area of the second sub-pixel SPX2, and the area of the third sub-pixel SPX3 may be substantially the same, and the other may be different from the two. Alternatively, the area of the first sub-pixel SPX1, the area of the second sub-pixel SPX2, and the area of the third sub-pixel SPX3 may be different from each other.

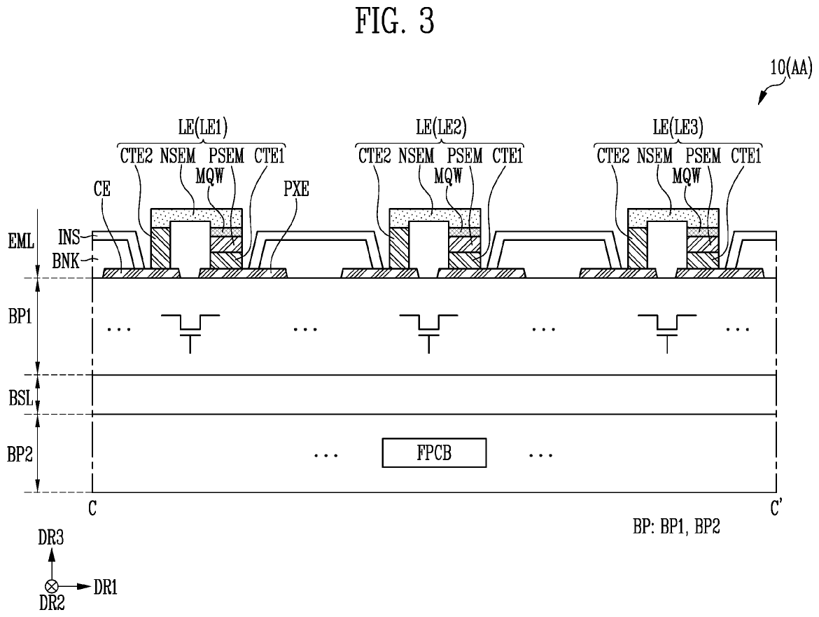

FIG. 3 is a cross-sectional view illustrating an example of a cross section of a pixel taken along the line C-C′ of FIG. 2 according to some embodiments. FIG. 3 may schematically show a cross-sectional structure of the display device 10 in the active area AA of FIG. 1.

Referring to FIG. 3, the display device 10 may include a base layer BSL, a backplane structure BP, and a light emitting element layer EML.

The base layer BSL may be a base substrate or a base member for supporting the display device 10. The base layer BSL may be a rigid substrate made of glass. Alternatively, the base layer BSL may be a flexible substrate capable of being bent, folded, or rolled. In this case, the substrate may include an insulating material such as a polymer resin such as polyimide.

The backplane structure BP may include a substrate, metal layers for forming pixel circuits and wirings, and insulating layers located between the metal layers.

The backplane structure BP may include a first backplane structure BP1 including a pixel circuit for driving light emitting elements LE and a second backplane structure BP2 including wirings electrically connected to a driving circuit unit FPCB.

The pixel circuits may include thin film transistors. The pixel circuits may further include storage capacitors. The pixel circuits may be electrically connected to the light emitting elements LE to provide electrical signals so that the light emitting elements LE emit light.

The first backplane structure BP1 may be located between the base layer BSL and the light emitting element layer EML. The second backplane structure BP2 may be located on a rear surface of the base layer BSL. According to some embodiments, the wirings formed on the second backplane structure BP2 may electrically connect the driving circuit unit FPCB and the pad PAD. For example, the second backplane structure BP2 may include the wirings for electrically connecting the driving circuit unit FPCB and the pad PAD.

The light emitting element layer EML may be located on the backplane structure BP (for example, the first backplane structure BP1). The light emitting element layer EML may include pixel electrodes PXE, common electrodes CE, and the light emitting elements LE. Each of the first sub-pixel SPX1, the second sub-pixel SPX2, and the third sub-pixel SPX3 may include a light emitting element LE connected to a pixel electrode PXE and a common electrode CE. According to some embodiments, the light emitting elements LE may include a first light emitting element LE1 configured to emit light of a first color and included in the first sub-pixel SPX1, a second light emitting element LE2 configured to emit light of a second color and included in the second sub-pixel SPX2, and a third light emitting element LE3 configured to emit light of a third color and included in the third sub-pixel SPX3. The pixel electrode PXE may be referred to as an anode electrode, and the common electrode CE may be referred to as a cathode electrode.

The pixel electrodes PXE and the common electrodes CE may be located on the backplane structure BP. Each of the pixel electrodes PXE may be electrically connected to a thin film transistor of the backplane structure BP. Accordingly, a pixel voltage or an anode voltage controlled by the thin film transistor may be applied to the pixel electrode PXE.

Each of the common electrodes CE may be electrically connected to a power source line formed on the backplane structure BP. Accordingly, one power source voltage of the power source line may be applied to the common electrodes CE.

The pixel electrodes PXE and the common electrodes CE may include a metal material having high reflectivity, such as a laminated structure of aluminum and titanium (Ti/Al/Ti), a laminated structure of aluminum and ITO (ITO/Al/ITO), an APC alloy, and a laminated structure of an APC alloy and ITO (ITO/APC/ITO). The APC alloy may be an alloy of silver (Ag), palladium (Pd), and copper (Cu).

In FIG. 3, embodiments in which each of the light emitting elements LE is a flip chip type micro LED in which a first contact electrode CTE1 and a second contact electrode CTE2 are arranged to face the pixel electrode PXE and the common electrode CE, is shown as an example. However, the shape of the light emitting element LE is not necessarily limited thereto.

The light emitting element LE may include an inorganic material such as GaN. The light emitting element LE may have a length of several to hundreds of μm in each of a first direction DR1, a second direction DR2, and a third direction DR3. For example, the light emitting element LE may have a length of approximately 100 μm or less in each of the first direction DR1, the second direction DR2, and the third direction DR3.

Each of the light emitting elements LE may be a light emitting structure including an n-type semiconductor NSEM, an active layer MQW, a p-type semiconductor PSEM, the first contact electrode CTE1, and the second contact electrode CTE2.

A portion of the n-type semiconductor NSEM may be located on the active layer MQW. A portion of the n-type semiconductor NSEM may be located on the second contact electrode CTE2. According to some embodiments, one surface of the n-type semiconductor NSEM may face a display surface. The n-type semiconductor NSEM may be made of GaN doped with an n-type conductive dopant such as Si, Ge, or Sn. However, the present disclosure is not necessarily limited thereto.

The active layer MQW may be located on a portion of one surface of the n-type semiconductor NSEM. The active layer MQW may be interposed between the n-type semiconductor NSEM and the p-type semiconductor PSEM. The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN, but the present disclosure is not limited thereto. Alternatively, the active layer MQW may have a structure in which semiconductor materials having high band gap energy and semiconductor materials having low band gap energy are alternately stacked. Alternatively, the active layer MQW may include group 3 to group 5 semiconductor materials according to the wavelength range of emitted light.

The p-type semiconductor PSEM may be located on one surface of the active layer MQW. The p-type semiconductor PSEM may be made of GaN doped with a p-type conductive dopant such as Mg, Zn, Ca, Se, or Ba. However, the present disclosure is not necessarily limited thereto.

The first contact electrode CTE1 may be located on the p-type semiconductor PSEM, and the second contact electrode CTE2 may be located on the other portion of one surface of the n-type semiconductor NSEM. The other portion of one surface of the n-type semiconductor NSEM on which the second contact electrode CTE2 is located may be arranged to be spaced apart from the portion of one surface of the n-type semiconductor NSEM on which the active layer MQW is located.

The first contact electrode CTE1 and the pixel electrode PXE may be adhered to each other through a conductive adhesive member such as an anisotropic conductive film (ACF) or an anisotropic conductive paste (ACP). Alternatively, the first contact electrode CTE1 and the pixel electrode PXE may be bonded to each other through a soldering process.

Meanwhile, a bank BNK covering an edge of the pixel electrode PXE and an edge of the common electrode CE may be located on the backplane structure BP. The bank BNK may be formed of an organic layer such as an acryl resin, an epoxy resin, a phenolic resin, a polyamide resin, or a polyimide resin.

An insulating layer INS may be located on the bank BNK. The insulating layer INS may cover the edge of the pixel electrode PXE and the edge of the common electrode CE. The insulating layer INS may be formed of an inorganic layer, for example, a silicon nitride layer, a silicon oxynitride layer, a silicon oxide layer, a titanium oxide layer, or an aluminum oxide layer.

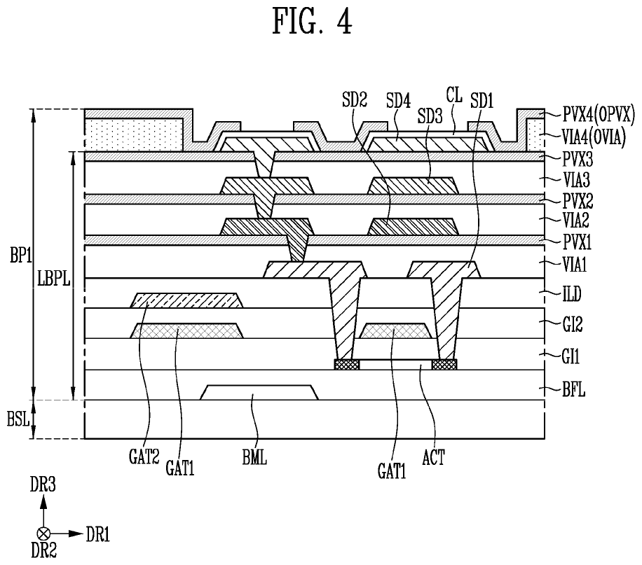

FIG. 4 is a cross-sectional view illustrating an example of a portion of a first backplane layer of FIG. 3.

Referring to FIG. 4, the first backplane structure BP1 may be located on the base layer BSL and may include a first backplane layer LBPL and an outer structure located on the first backplane layer LBPL.

The first backplane layer LBPL may include conductive layers and insulating layers located between the outer structure of the first backplane structure BP1 and the base layer BSL.

The first backplane layer LBPL may have a shape remaining after at least a portion of a structure in which a lower auxiliary electrode layer BML, a buffer layer BFL, an active layer ACT, a first gate insulating layer Gl1, a first gate electrode layer GAT1, a second gate insulating layer GI2, a second gate electrode layer GAT2, an interlayer insulating layer ILD, a first interlayer conductive layer SD1, a first via layer VIA1, a first protective layer PVX1, a second interlayer conductive layer SD2, a second via layer VIA2, a second protective layer PVX2, a third interlayer conductive layer SD3, a third via layer VIA3, and a third protective layer PVX3 are sequentially stacked is patterned.

For example, the electrode layers may be patterned as a single structure to form the pixel circuit. For example, a portion of the active layer ACT, a portion of the first gate electrode layer GAT1, and a portion of the first interlayer conductive layer SD1 may form a driving transistor.

According to some embodiments, the buffer layer BFL, the first gate insulating layer Gl1, the second gate insulating layer GI2, the interlayer insulating layer ILD, and the first to third protective layers PVX1 to PVX3 may include an inorganic material. According to some embodiments, each of the first to third protective layers PVX1 to PVX3 may form a hole exposing a via layer located thereunder. For example, the first protective layer PVX1 may form a hole exposing the first via layer VIA1, the second protective layer PVX2 may form a hole exposing the second via layer VIA2, and the third protective layer PVX3 may form a hole exposing the third via layer VIA3. For example, each of the holes may form an outgassing path for discharging gas in the backplane structure BP during a manufacturing process.

According to some embodiments, the active layer ACT may include a semiconductor. For example, the active layer ACT may include at least one selected from the group consisting of polysilicon, low temperature polycrystalline silicon (LTPS), amorphous silicon, and an oxide semiconductor.

According to some embodiments, the first to third via layers VIA1 to VIA3 may include an organic material.

According to some embodiments, the lower auxiliary electrode layer BML, the first and second gate electrode layers GAT1 and GAT2, and the first to third interlayer conductive layers SD1 to SD3 may include a conductive material.

The number and material of the conductive layers and insulating layers forming the first backplane layer LBPL are not particularly limited to the above example, and the number and material of the conductive layers and insulating layers may be variously changed.

The outer structure located on the first backplane layer LBPL may include a fourth interlayer conductive layer SD4 and a connection conductive layer CL.

According to some embodiments, the fourth interlayer conductive layer SD4 and the connection conductive layer CL may include a conductive material. According to some embodiments, the connection conductive layer CL may include a transparent electrode (for example, indium tin oxide (ITO)), but the present disclosure is not limited thereto.

A fourth via layer VIA4 may be located on the third protective layer PVX3. The fourth via layer VIA4 may include an organic material. The fourth via layer VIA4 may be provided as an outer via layer OVIA to be described with reference to FIG. 5. As such, the first backplane layer BP1 may include the outer via layer OVIA located thereon. The outer via layer OVIA may cover components below the outer via layer OVIA.

A fourth protective layer PVX4 may be located on the fourth via layer VIA4. The fourth protective layer PVX4 may cover the fourth via layer VIA4. The fourth protective layer PVX4 may expose a portion of the connection conductive layer CL while partially covering the conductive layer CL. The fourth protective layer PVX4 may include an inorganic material. The fourth protective layer PVX4 may be provided as an outer protective layer OPVX of FIG. 5.

According to some embodiments, the organic material may include at least one selected from the group consisting of an acrylic resin, an epoxy resin, a phenol resin, a polyamide resin, a polyimide resin, a polyester resin, a polyphenylenesulfide resin, and benzocyclobutene. However, the present disclosure is not limited thereto.

According to some embodiments, the inorganic material may include at least one selected from the group consisting of silicon nitride (SiNx), aluminum nitride (AlNx), titanium nitride (TiNx), silicon oxide (SiOx), aluminum oxide (AIOx), titanium oxide (TiOx), silicon oxycarbide (SiOxCy), and silicon oxynitride (SiOxNy). However, the present disclosure is not limited thereto.

FIG. 5 is a cross-sectional view taken along the line A-A′ of FIG. 1. FIG. 5 schematically shows an area adjacent to an edge of the display device 10. FIG. 5 shows the base layer BSL and the backplane structure BP without showing the light emitting element layer EML for convenience of description.

Referring to FIG. 5, the first backplane structure BP1 including the first backplane layer LBPL may be formed on one surface of the base layer BSL. The second backplane structure BP2 including a second backplane layer DBPL may be formed on the other surface of the base layer BSL.

The outer via layer OVIA may be located on the first backplane layer LBPL. The outer protective layer OPVX may be located on the outer via layer OVIA.

The outer via layer OVIA may be arranged over the peripheral area PA and the active area AA. For example, the outer via layer OVIA may overlap the peripheral area PA when viewed on a plane defined in the first direction DR1 and the second direction DR2. The outer via layer OVIA may overlap the active area AA when viewed on a plane.

The outer via layer OVIA may include an organic material, and gas generated within the first backplane structure BP1 may pass through the outer via layer OVIA.

The outer via layer OVIA may be exposed through a hole BH. For example, the outer via layer OVIA may not be covered by the outer protective layer OPVX in a region corresponding to the hole BH. According to some embodiments, the hole BH may be an outgassing path through which gas is discharged.

The outer protective layer OPVX may be located on the outer via layer OVIA. The outer protective layer OPVX may include a first outer protective layer OPVX1 and a second outer protective layer OPVX2.

The first outer protective layer OPVX1 and the second outer protective layer OPVX2 may be spaced apart from each other. For example, a dividing line SL dividing positions of the first outer protective layer OPVX1 and the second outer protective layer OPVX2 may overlap the active area AA.

The first outer protective layer OPVX1 may be located in the active area AA. The first outer protective layer OPVX1 may not be located in the peripheral area PA. The first outer protective layer OPVX1 may expose the outer via layer OVIA in the active area AA. For example, the first outer protective layer OPVX1 may form the hole BH. The first outer protective layer OPVX1 may expose the outer via layer OVIA through the hole BH in the active area AA.

The hole BH may include a plurality of holes. The hole BH may have one or more shapes selected from the group consisting of a circular shape, an elliptical shape, and a polygonal shape. The shape and arrangement structure of holes BH are not particularly limited.

At least a portion of the second outer protective layer OPVX2 may be located in the peripheral area PA, and at least another portion of the second outer protective layer OPVX2 may be located in the active area AA. For example, the second outer protective layer OPVX2 may overlap the peripheral area PA when viewed on a plane. The second outer protective layer OPVX2 may overlap the active area AA when viewed on a plane. The second outer protective layer OPVX2 may include a body portion located in the peripheral area PA and an extended portion extending from the body portion and located in the active area AA. According to some embodiments, the extended portion of the second outer protective layer OPVX2 may be spaced apart from the first outer protective layer OPVX1 with the hole BH interposed therebetween.

A lower via layer DVIA may be located on the second backplane layer DBPL. A lower protective layer DPVX may be located on the lower via layer DVIA. In some embodiments, the lower via layer DVIA may be formed of substantially the same material as the outer via layer OVIA, and the lower protective layer DPVX may be formed of substantially the same material as the outer protective layer OPVX.

The lower via layer DVIA may be located over the peripheral area PA and the active area AA. For example, the lower via layer DVIA may overlap the peripheral area PA when viewed on a plane defined in the first direction DR1 and the second direction DR2. The lower via layer DVIA may overlap the active area AA when viewed on a plane defined by the first direction DR1 and the second direction DR2. The lower via layer DVIA may include an organic material, and gas generated within the second backplane structure BP2 may pass through the lower via layer DVIA.

The lower via layer DVIA may be exposed through a hole BH of the lower protective layer DPVX. According to some embodiments, the hole BH may be, for example, an outgassing path through which gas generated during a manufacturing process is discharged.

The lower protective layer DPVX may be located on the lower via layer DVIA. The lower protective layer DPVX may include a first lower protective layer DPVX1 and a second lower protective layer DPVX2.

The first lower protective layer DPVX1 and the second lower protective layer DPVX2 may be spaced apart from each other. For example, a division line SL dividing positions of the first lower protective layer DPVX1 and the second lower protective layer DPVX2 may overlap the active area AA.

The first lower protective layer DPVX1 may be located in the active area AA. The first lower protective layer DPVX1 may not be located in the peripheral area PA. The first lower protective layer DPVX1 may expose the lower via layer DVIA in the active area AA. For example, the first lower protective layer DPVX1 may have a hole BH. The first lower protective layer DPVX1 may expose the lower via layer DVIA through the hole BH in the active area AA.

The hole BH may have one or more shapes selected from the group consisting of a circular shape, an elliptical shape, and a polygonal shape. The shape and arrangement structure of holes BH are not particularly limited.

At least a portion of the second lower protective layer DPVX2 may be located in the peripheral area PA, and at least another portion of the second lower protective layer DPVX2 may be located in the active area AA. For example, the second lower protective layer DPVX2 may overlap the peripheral area PA when viewed on a plane. The second lower protective layer DPVX2 may further overlap the active area AA when viewed on a plane. The second lower protective layer DPVX2 may include a body portion located in the peripheral area PA and an extended portion extending from the body portion and located in the active area AA. According to some embodiments, the extended portion of the second lower protective layer DPVX2 may be spaced apart from the first lower protective layer DPVX1 with the hole BH interposed therebetween.

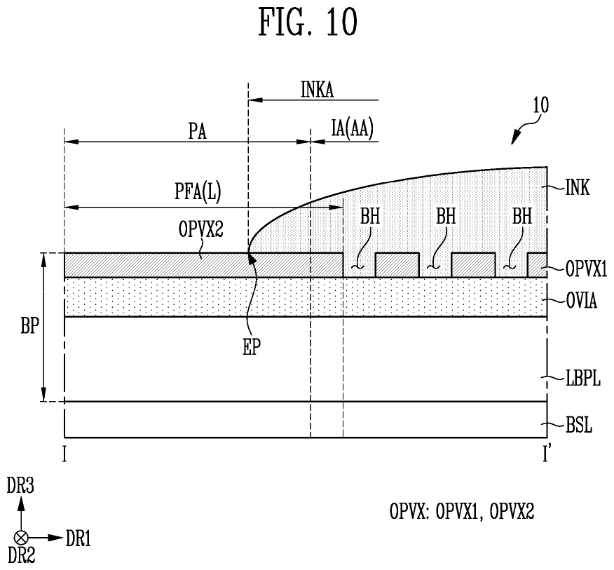

According to some embodiments, the second outer protective layer OPVX2 and the second lower protective layer DPVX2 may entirely cover the peripheral area PA. Each of the second outer protective layer OPVX2 and the second lower protective layer DPVX2 may not expose the outer via layer OVIA and the lower via layer DVIA in the peripheral area PA. For example, each of the second outer protective layer OPVX2 and the second lower protective layer DPVX2 may entirely cover the outer via layer OVIA and the lower via layer DIVIA in the peripheral area PA. Accordingly, in a manufacturing process of the display device 10, residual risk of process residues in the peripheral area PA can be prevented. Details regarding this will be described later with reference to FIG. 10.

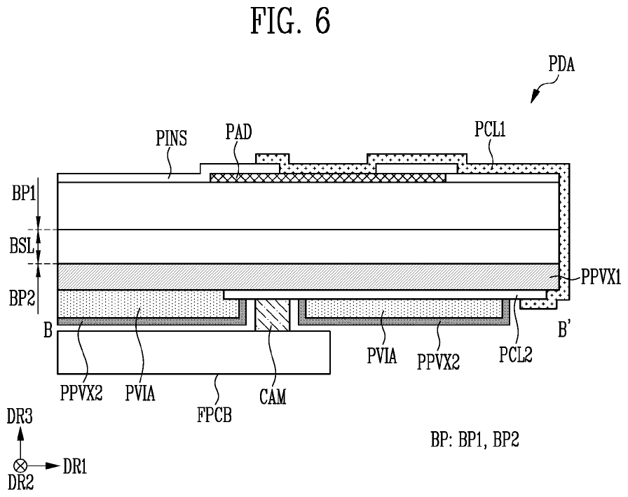

FIG. 6 is a cross-sectional view taken along the line B-B′ of FIG. 1. FIG. 6 may schematically show an area adjacent to an edge of the display device 10. FIG. 6 shows some structures of the base layer BSL and the backplane structure BP without showing the light emitting element layer EML for convenience of description.

Referring to FIG. 6, the first backplane structure BP1 may include the pad PAD and a pad insulating layer PINS.

The pad PAD may be electrically connected to the wirings (for example, the data lines) of the display device 10. The wirings may be formed by one or more of the conductive layers for forming the first backplane structure BP1. The pad PAD may include one or more layers. The pad PAD may be formed by one or more of the conductive layers for forming the first backplane structure BP1. However, the present disclosure is not limited to a specific example.

The pad PAD may be located on any layer of the first backplane structure BP1 and may be covered by the pad insulating layer PINS. The pad insulating layer PINS may expose a portion of the pad PAD, and the pad PAD and a first pad connection line PCL1 may be electrically connected to each other at the exposed portion. The first pad connection line PCL1 may be a side wiring.

A portion of the first pad connection line PCL1 may be located on a rear surface of the base layer BSL and may be formed in the second backplane structure BP2. The first pad connection line PCL1 may be electrically connected to a second pad connection line PCL2 formed in the second backplane structure BP2.

The second backplane structure BP2 may include a first pad protective layer PPVX1, a pad via layer PVIA, and a second pad protective layer PPVX2. The second backplane structure BP2 may include the second pad connection line PCL2.

The second pad connection line PCL2 may be located on the first pad protective layer PPVX1 and electrically connect the first pad connection line PCL1 and the driving circuit unit FPCB. For example, a portion of the second pad connection line PCL2 may be electrically connected to the first pad connection line PCL1, and another portion of the second pad connection line PCL2 may be electrically connected to the driving circuit unit FPCB through a conductive adhesive member CAM.

The first pad protective layer PPVX1 may be located on the rear surface of the base layer BSL and may include an inorganic material. The pad via layer PVIA may be located on the first pad protective layer PPVX1 and may include an organic material. The second pad protective layer PPVX2 may be located on the pad via layer PVIA and may include an inorganic material.

The conductive adhesive member CAM may be an anisotropic conductive film or an anisotropic conductive paste. The driving circuit unit FPCB may include a flexible circuit board. The driving circuit unit FPCB may include a source driving circuit for supplying data voltages to the data lines.

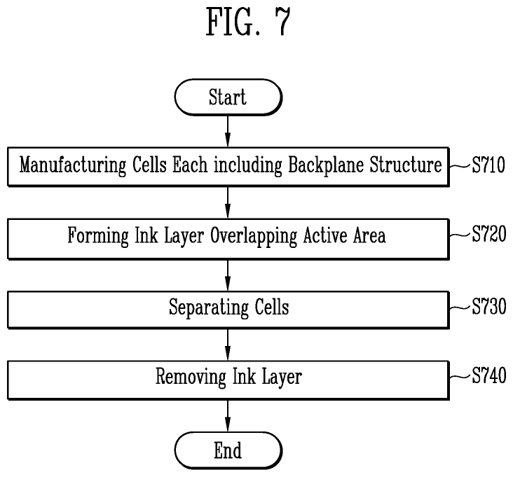

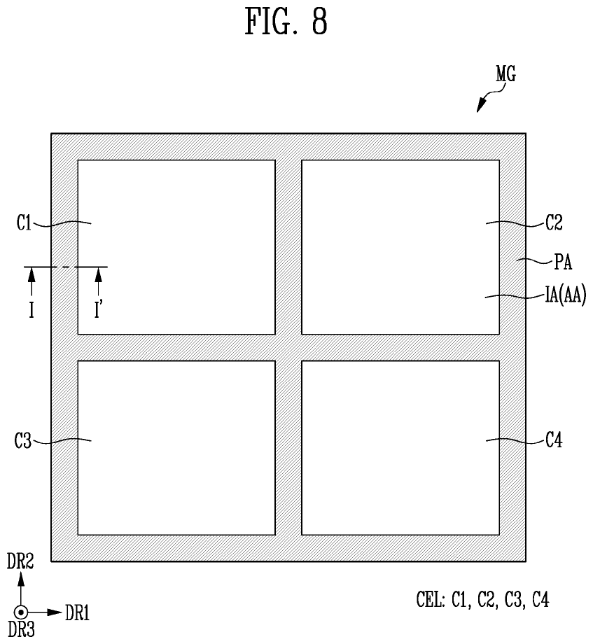

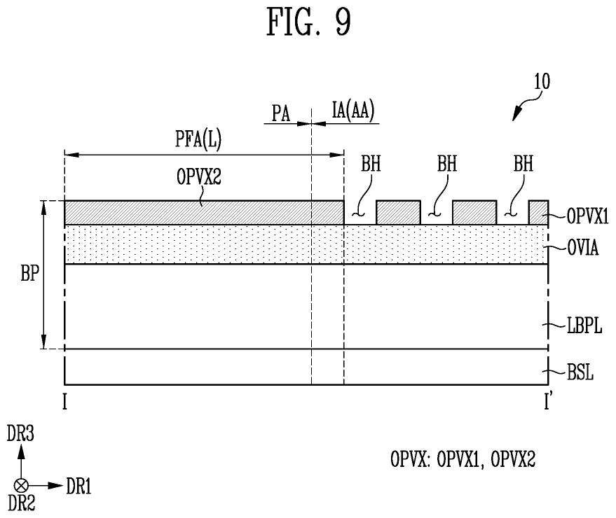

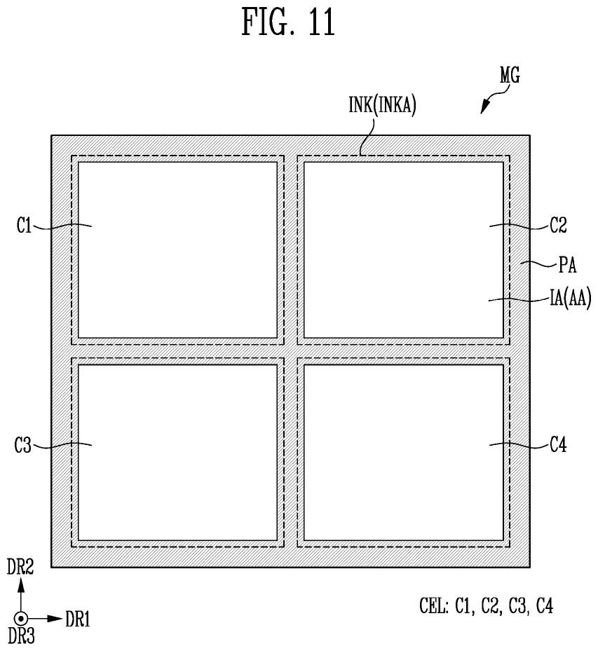

FIG. 7 is a flowchart illustrating a manufacturing method of a display device according to some embodiments of the present invention. FIG. 8 is a plan view illustrating cells in operation S710 of FIG. 7. FIG. 9 is a cross-sectional view taken along the line I-I′ of FIG. 8. FIG. 10 is a cross-sectional view taken along the line I-l′ of FIG. 8 in operation S720 of FIG. 7. FIG. 11 is a plan view illustrating cells in operation S720 of FIG. 7. The line I-l′ of FIG. 8 may correspond to the line A-A′ of FIG. 1.

According to some embodiments, the backplane structure BP may be a structure formed on one surface and/or the other surface of the base layer BSL in the display device 10 of FIG. 5. For example, the backplane structure BP may refer to the first backplane structure BP1 and/or the second backplane structure BP2 of FIG. 5.

Referring to FIG. 7, a manufacturing method of the display device 10 according to some embodiments may include manufacturing cells each including a backplane structure (S710), forming an ink layer (S720), separating the cells (S730), and removing the ink layer (S740).

Referring to FIGS. 7 and 8, in the operation S710, cells CEL may be formed (or defined) on a mother substrate MG. Each of the cells CEL may include a backplane structure BP. The mother substrate MG may be a base layer BSL for the backplane structure BP of each cell CEL.

According to some embodiments, the mother substrate MG may include the base layer BSL for forming the cells CEL. The mother substrate MG may be a component for simultaneously manufacturing two or more display devices. According to some embodiments, the mother substrate MG may be separated to form the base layer BSL for each cell CEL. Each of the cells CEL may correspond to the display device of FIG. 1. For example, the display device of FIG. 1 may be manufactured from each of the cells CEL.

The cells CEL may include a first cell C1, a second cell C2, a third cell C3, and a fourth cell C4. The number of cells CEL is not particularly limited.

Referring to FIG. 9 along with FIGS. 7 and 8, the backplane structure BP may be formed on the base layer BSL. The backplane structure BP may include patterned conductive layers and insulating layers. The conductive layers and the insulating layers may be formed through a known patterning process (for example, a photolithography process, etc.) using a mask.

In this operation, a first backplane layer LBPL may be formed on the base layer BSL, and an outer via layer OVIA may be formed on the first backplane layer LBPL. Additionally, a first outer protective layer OPVX1 and a second outer protective layer OPVX2 may be patterned on the outer via layer OVIA.

In this operation, an outer protective layer OPVX may form a hole BH exposing the outer via layer OVIA. In this case, the hole BH may be formed in an inner area IA without being located in a peripheral area PA. Here, the inner area IA may be an area defined as an active area AA as light emitting elements LE are formed in subsequent processes.

In this operation, the second outer protective layer OPVX2 may be patterned from the peripheral area PA to the inner area IA. Accordingly, a peripheral cover area PFA may be defined. In this case, the second outer protective layer OPVX2 may entirely cover the peripheral area PA, and the hole BH may not be formed in the peripheral area PA. According to some embodiments, the peripheral area PA may correspond to an edge area of each cell CEL. For example, the peripheral area PA may include an area between the cells CEL and may be the outermost area of each cell CEL. The hole BH may not be formed in the edge area of each cell CEL. For example, the hole BH may not be formed in an area between adjacent cells CEL, and the hole BH may not be formed in the outermost area of each cell CEL.

Next, referring to FIGS. 7, 10, and 11, in the operation S720, an ink layer INK may be formed on the outer via layer OVIA and the outer protective layer OPVX.

In this operation, the ink layer INK may cover the active area AA and the hole BH. Also, the ink layer INK may cover a portion of the peripheral area PA. The ink layer INK may overlap the active area AA and the peripheral area PA when viewed on a plane. The ink layer INK may overlap the peripheral cover area PFA when viewed on a plane.

An area where the ink layer INK is located may be defined as an ink area INKA. In FIG. 11, the ink area INKA may cover each cell CEL, and may have an area larger than each cell CEL.

The ink area INKA may be determined based on an end portion EP of the ink layer INK. The end portion EP of the ink layer INK may be located within the peripheral area PA. In this case, the end portion EP of the ink layer INK may be in contact with the second outer protective layer OPVX2. The end portion EP may refer to the outermost portion of the ink layer INK based on a direction from the inner area IA to the peripheral area PA.

When a hole is formed in the peripheral area, the end portion EP of the ink layer INK may be adjacent to the hole formed in the peripheral area. In this case, a portion of the ink layer INK may be broken around the end portion EP due to a operation difference in a surface caused by the hole. When a portion of the ink layer INK is broken, the broken portion of the ink layer INK may remain even after the manufacturing process, which may reduce the visibility of the display device 10. On the other hand, according to some embodiments of the present invention, the end portion EP of the ink layer INK may be formed to extend to the peripheral area PA, and the second outer protective layer OPVX2 that entirely covers the peripheral area PA may not have the hole BH. Accordingly, the ink layer INK may extend to the end portion EP thereof without discontinuity. Accordingly, the visibility of the display device 10 can be improved.

In this operation, the ink layer INK may not contact the outer via layer OVIA in the peripheral area PA. For example, the ink layer INK may be separated from the outer via layer OVIA by the second outer protective layer OPVX2 in the peripheral area PA.

In this operation, the ink layer INK may be in contact with the outer via layer OVIA in the active area AA. For example, the ink layer INK may be in contact with the outer via layer OVIA at the hole BH in the active area AA.

According to some embodiments, the ink layer INK may be a protective layer to protect the internal structure of the cells CEL when separating the cells CEL in a subsequent process. According to some embodiments, the ink layer INK may include an acrylic material. For example, the ink layer INK may include an acrylic oligomer. However, the present disclosure is not necessarily limited thereto, and the ink layer INK may include various oligomers, etc.

Referring to FIG. 7, in the operation S730, the cells CEL on the mother substrate MG may be separated to form a separate display panel.

In this operation, the cells CEL on the mother substrate MG may be cut. For example, in this operation, a scribing process may be performed to separate the cells CEL. However, the present disclosure is not necessarily limited to the above-described example, and various processes may be applied to cut the cells CEL in this operation.

In this operation, the second outer protective layer OPVX2 formed in the cells CEL may be cut. According to some embodiments, the second outer protective layer OPVX2 may be cut, but the first outer protective layer OPVX1 may not be cut.

According to some embodiments, the location of a cutting line where the cutting process is performed may be formed within the peripheral area PA located between the cells CEL. According to some embodiments, the cutting line on which the cutting process is performed may not overlap the ink layer INK when viewed on a plane.

In the operation S740, the ink layer INK may be removed. The ink layer INK may be removed by various methods.

A process performed in this operation may be referred to as a peeling process. In this operation, the ink layer INK may be removed to expose the outer protective layer OPVX, and the outer via layer OVIA may be exposed in the hole BH. In some embodiments, after the operation S740, a film layer that protects the backplane structure BP may be formed. For example, the film layer may be arranged to cover the outer protective layer OPVX and the outer via layer OVIA. Accordingly, the laminated structure including the backplane structure BP manufactured as described above can be safely transported to subsequent processing equipment.

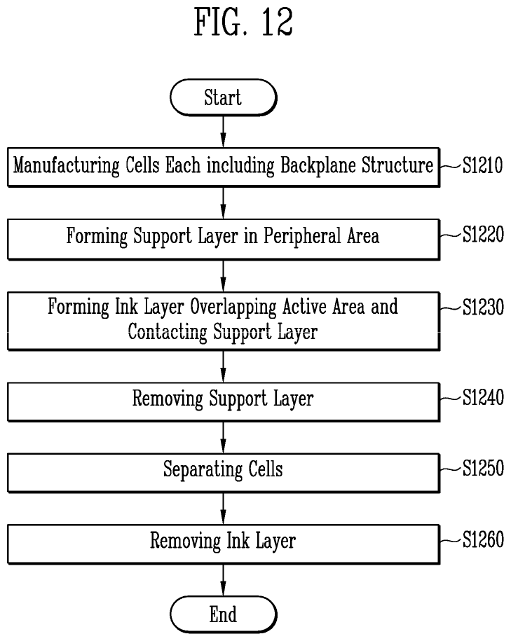

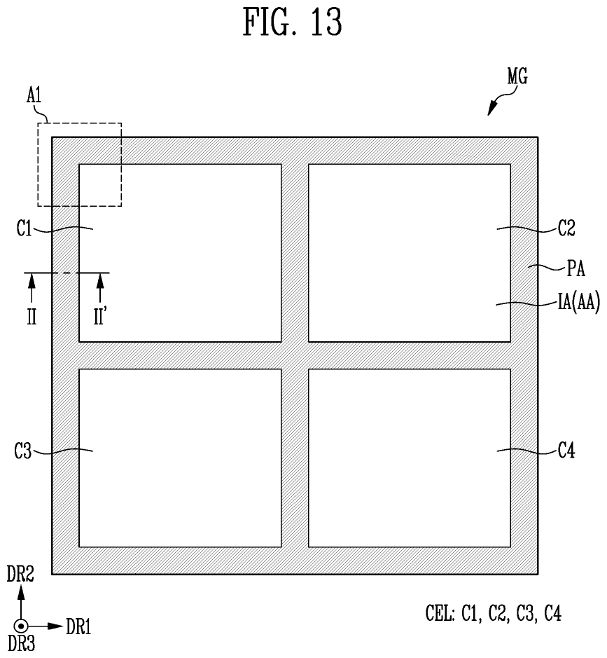

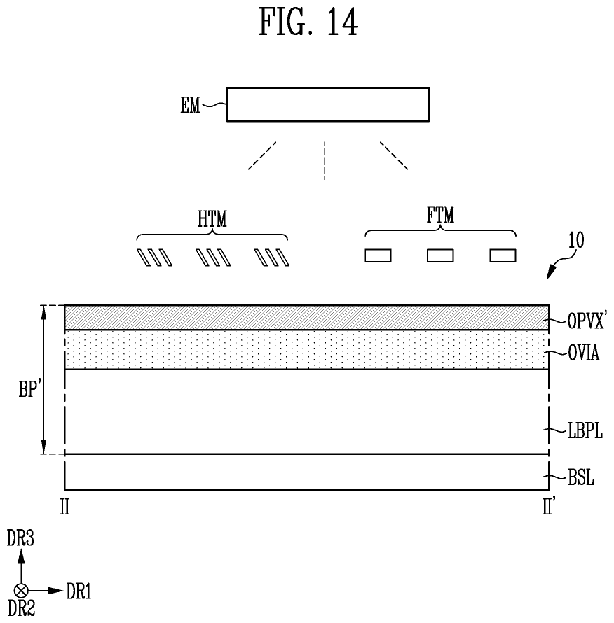

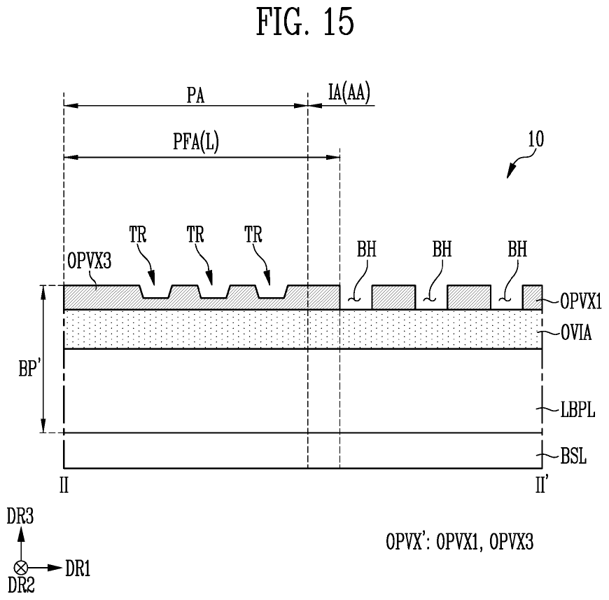

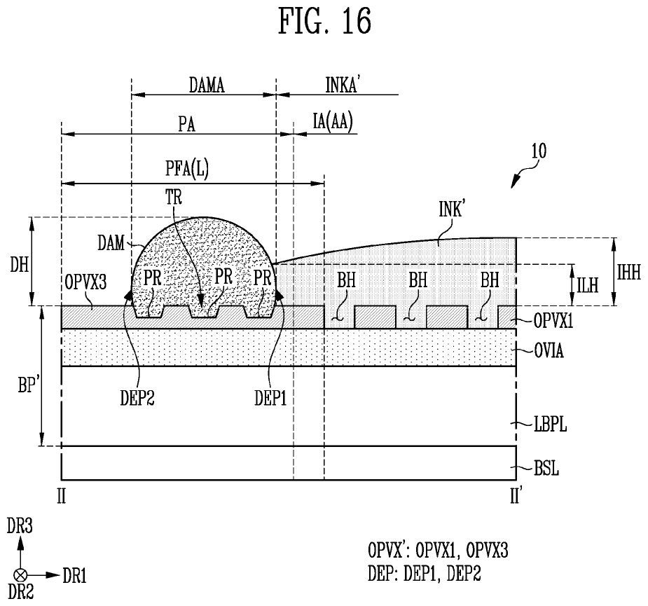

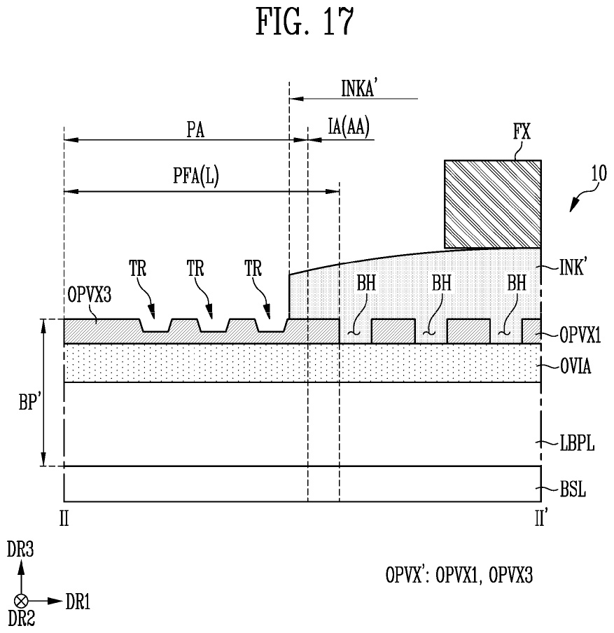

FIG. 12 is a flowchart illustrating a manufacturing method of a display device according to some embodiments of the present invention. FIG. 13 is a plan view illustrating cells in operation S1210 of FIG. 12. FIGS. 14 and 15 are cross-sectional views taken along the line II-II′ of FIG. 13 to explain a manufacturing method of operation S1210 of FIG. 12. FIG. 16 is a cross-sectional view taken along the line II-II′ of FIG. 13 in operation S1230 of FIG. 12. FIG. 17 is a cross-sectional view taken along the line II-II′ of FIG. 13 in operation S1250 of FIG. 12.

According to some embodiments, a backplane structure BP′ may be a structure formed on one side and/or the other side of the base layer BSL in the display device 10 of FIG. 5. For example, the backplane structure BP′ may refer to the first backplane structure BP1 and/or the second backplane structure BP2 of FIG. 5.

Referring to FIG. 12, a manufacturing method of the display device 10 according to some embodiments may include manufacturing cells each including a backplane structure (S1210), forming a support layer in a peripheral area (S1220), forming an ink layer overlapping an inner area and contacting the support layer (S1230), removing the support layer (S1240), separating the cells (S1250), and removing the ink layer (S1260).

The operation S1210 of FIG. 12 may be explained similarly to the operation S710 of FIG. 7.

Referring to FIGS. 12 to 14, in the operation S1210, each of the cells CEL may include the backplane structure BP′. A mother substrate MG may be a base layer BSL for the backplane structure BP′ of each cell CEL.

The backplane structure BP′ may be formed on the base layer BSL. A first backplane layer LBPL may be formed on the base layer BSL, and an outer via layer OVIA may be formed on the first backplane layer LBPL. Additionally, a first outer protective layer OPVX1 and a third outer protective layer OPVX3 may be patterned on the outer via layer OVIA.

Referring to FIGS. 14 and 15, in this operation, an outer protective layer OPVX′ may form a hole BH exposing the outer via layer OVIA. For example, light from an exposure device EM may be irradiated to the outer protective layer OPVX′. In this case, the light may pass through a full tone mask FTM and be irradiated to the first outer protective layer OPVX1. Accordingly, the hole BH exposing the outer via layer OVIA may be formed in a specific area of the first outer protective layer OPVX1. In this case, the hole BH may be formed in the inner area IA without being located in the peripheral area PA. Here, the inner area IA may be an area defined as an active area AA as light emitting elements LE are formed in subsequent processes.

Also, the outer protective layer OPVX′ may form a trench TR that does not expose the outer via layer OVIA. For example, light from the exposure device EM may pass through a halftone mask HTM and be irradiated to the third outer protective layer OPVX3. In this case, the intensity of light irradiated to the third outer protective layer OPVX3 may be adjusted through the halftone mask HTM. Accordingly, the intensity of light irradiated to the third outer protective layer OPVX3 may be relatively weaker than the intensity of light irradiated to the first outer protective layer OPVX1. Accordingly, the trench TR that does not expose the outer via layer OVIA may be formed in a specific area of the third outer protective layer OPVX3. In this case, the trench TR may be formed in the peripheral area PA. The trench TR may be formed in a peripheral cover area PFA.

As shown in FIG. 15, the trench TR may have an inverted trapezoidal shape in cross section, but the present disclosure is not limited thereto.

The outer protective layer OPVX′ may include an inorganic material, similar to the outer protective layer OPVX of FIG. 9. For example, the third outer protective layer OPVX3 may include an inorganic material such as silicon nitride (SiNx). The outer via layer OVIA may include an organic material, as described above.

Referring to FIGS. 12 and 16, in the operation S1220, a support layer DAM may be formed on the backplane structure BP′.

The support layer DAM may cover the peripheral area PA and the trench TR. Also, the support layer DAM may cover the peripheral cover area PFA. The support layer DAM may overlap the peripheral area PA and the peripheral cover area PFA when viewed on a plane.

In some embodiments, the support layer DAM may have a dam shape. For example, the support layer DAM may extend in the first direction DR1 and the second direction DR2 along an edge of each cell CEL to surround a corresponding cell.

According to some embodiments, an area where the support layer DAM is located may be defined as a support area DAMA. For example, the support area DAMA may be determined based on end portions DEP of the support layer DAM. For example, the support area DAMA may be defined as an area from a first end DEP1 located on one side of the support layer DAM to a second end DEP2 located on the other side. The end portions DEP of the support layer DAM may be located in the peripheral area PA. The end portions DEP of the support layer DAM may be located in the peripheral cover area PFA. Accordingly, the support area DAMA may be located within the peripheral cover area PFA.

In this operation, the support layer DAM may be primarily cured. For example, UV curing can be achieved by irradiating ultraviolet (UV) rays to the support layer DAM. When ultraviolet rays are irradiated to the support layer DAM, bonding between molecules constituting the support layer DAM may be promoted, and thus the support layer DAM can be cured.

In this operation, the support layer DAM may be in contact with the third outer protective layer OPVX3 in the peripheral area PA. For example, a protrusion PR of the support layer DAM may be in contact with the third outer protective layer OPVX3 through the trench TR. The support layer DAM may not contact the outer via layer OVIA.

Referring to FIGS. 12 and 16, in the forming the ink layer overlapping the inner area and contacting the support layer (S1230), an ink layer INK′ may be formed on the backplane structure BP′.

The ink layer INK′ may cover the active area AA and the hole BH. Also, the ink layer INK′ may cover a portion of the peripheral area PA. The ink layer INK′ may overlap the active area AA and the peripheral area PA when viewed on a plane. The ink layer INK′ may overlap the peripheral cover area PFA when viewed on a plane.

The ink layer INK′ and the support layer DAM may be made of the same material as the ink layer INK of FIG. 10. For example, the ink layer INK′ and the support layer DAM may include an acrylic material such as an acrylic oligomer.

In this operation, the ink layer INK′ may be cured. For example, UV curing can be achieved by irradiating ultraviolet (UV) rays to the ink layer INK. In addition, the support layer DAM may be secondarily cured. Accordingly, the support layer DAM may undergo two curing processes, and the hardness of the support layer DAM and the ink layer INK may be different. This difference in hardness can allow the support layer DAM to be easily removed. Details about this will be described later.

In this operation, the ink layer INK′ may be in contact with the support layer DAM in the peripheral area PA. For example, the ink layer INK′ may be in contact with the first end DEP1 in the peripheral area PA. Accordingly, the ink layer INK′ may entirely cover the active area AA and protect the backplane structure BP′ included in the active area AA in a subsequent process.

The ink layer INK′ may be supported by the support layer DAM. For example, before the ink layer INK′ is cured, the ink layer INK′ may flow in the active area AA in the first direction DR1 and/or in a direction opposite to the first direction DR1 due to its fluidity. In this case, the ink layer INK′ may be in contact with the support layer DAM. For example, the ink layer INK′ may be in contact with the first end DEP1 of the support layer DAM. Accordingly, the ink layer INK′ may no longer flow and may be supported in the first direction DR1 by the support layer DAM.

In this way, the fluidity of the ink layer INK′ may be controlled by providing the support layer DAM, and thus the height of the ink layer INK′ can be controlled to be relatively uniform. For example, compared to the ink layer INK of FIG. 10, a difference between the highest height IHH and the lowest height ILH of the ink layer INK′ may not be large. The highest height IHH may be the length from an upper surface of the outer protective layer OPVX′ to the most protruding portion of the ink layer INK′ in the third direction DR3. The lowest height ILH may be the length from a portion where the ink layer INK′ contacts the first end DEP1 of the support layer DAM to the outermost portion of the ink layer INK′ in the third direction DR3 from the upper surface of the outer protective layer OPVX′.

Meanwhile, the fluidity of the support layer DAM and the fluidity of the ink layer INK′ may be different from each other. For example, the support layer DAM and the ink layer INK′ may have different degrees of flow on a plane. For example, the support layer DAM and the ink layer INK′ may include an acrylic oligomer, and the fluidity when the support layer DAM and the ink layer INK′ are in contact with an inorganic material may be lower than the fluidity when the support layer DAM and the ink layer INK′ are in contact with an organic material. Accordingly, the fluidity when the support layer DAM is in contact with the third outer protective layer OPVX3 may be lower than the fluidity when the ink layer INK′ is in contact with the outer via layer OVIA.

The support layer DAM may have relatively lower fluidity than the ink layer INK′ due to the trench TR structure, and the support layer DAM may flow in a relatively small amount over the outer protective layer OPVX′. For example, when the trench is not formed, the support layer DAM may flow in a relatively larger amount over a plane due to its fluidity. Accordingly, the highest height of the support layer DAM may be lower than the highest height of the ink layer INK′. Therefore, there may be a risk that the support layer DAM does not stably support the ink layer INK′.

According to some embodiments of the present invention, the fluidity of the support layer DAM may be controlled by a plurality of slits included in the trench TR. The trench TR may have partition walls recessed in a direction opposite to the third direction DR3. The flow of the support layer DAM in the first direction DR1 and/or the second direction DR2 may be blocked by the partition walls. Accordingly, the fluidity of the support layer DAM may be controlled so that the highest height DH of the support layer DAM may be higher than the highest height IHH of the ink layer INK′. Ultimately, the fluidity of the support layer DAM can be controlled, and the support layer DAM may stably support the ink layer INK′.

FIG. 16 shows embodiments in which three trenches TR are provided. However, embodiments are not limited thereto. The number of trenches TR may be varied in a range that can control the fluidity of the support layer DAM.

In addition, an area where the ink layer INK′ is located may be defined as an ink area INKA′. This ink area INKA′ may be determined by the support layer DAM. For example, the ink area INKA′ may be determined based on the position of an end portion DEP of the support layer DAM. For example, the ink area INKA′ may be determined based on the position where the first end DEP1 of the support layer DAM is located on the peripheral area PA.

Referring to FIGS. 12 and 17, in the operation S1240, the support layer DAM may be removed. For example, the ink layer INK′ may not be removed, but only the support layer DAM may be removed. The support layer DAM may be removed similarly to the ink layer INK in FIG. 7.

The support layer DAM may be removed using a peelable tape. For example, the peelable tape may be entirely attached to an upper surface of the support layer DAM. Thereafter, the peelable tape attached to the support layer DAM may be pulled in the third direction DR3. Accordingly, the support layer DAM may be separated from the outer protective layer OPVX′ by the peelable tape.

For example, the peelable tape may apply tension to the support layer DAM in the third direction DR3. In this case, the tension may be applied starting from a portion where the adhesion between the support layer DAM and the outer protective layer OPVX′ is relatively weak. For example, the tension may be applied to portions adjacent to the end portions DEP of the support layer DAM. Accordingly, the support layer DAM can be separated from the outer protective layer OPVX′ from the portions adjacent to the end portions DEP of the support layer DAM and can be removed.

In addition, as described above, the hardness of the support layer DAM and the ink layer INK′ may be different from each other, and the adhesion between the support layer DAM and the ink layer INK′ may be relatively weak compared to the adhesion between the support layer DAM and the outer protective layer OPVX″. Accordingly, only the support layer DAM can be removed from the outer protective layer OPVX′.

In this operation, a fixing member FX may be located on the ink layer INK′ to remove only the support layer DAM. For example, the fixing member FX may be arranged to overlap the ink layer INK′. In a process of removing the support layer DAM, since the support layer DAM and the ink layer INK′ are in contact with each other, there may be a risk that a portion of the ink layer INK′ is removed around the first end DEP1 of the support layer DAM.

In this case, the fixing member FX may fix the ink layer INK′ so that the ink layer INK′ is not separated from the outer protective layer OPVX′. For example, the fixing member FX located on the ink layer INK′ may apply force to the ink layer INK′ in a direction opposite to the third direction DR3. According to some embodiments of the present invention, only the support layer DAM can be stably removed.

The shape and position of the fixing member FX are not limited to the present disclosure as long as it can fix the ink layer INK′. After the operation S1240 is completed, the fixing member FX may be removed from the ink layer INK′.

In the operation S1250, the cells CEL on the mother substrate MG may be separated to form separate panels. The operation S1250 of FIG. 12 may be explained similarly to the operation S730 of FIG. 7.

In this operation, the third outer protective layer OPVX3 formed in the cells CEL may be cut. According to some embodiments, the third outer protective layer OPVX3 may be cut, but the first outer protective layer OPVX1 may not be cut.

According to some embodiments, a cutting line on which the cutting process is performed may be located in the peripheral area PA located between the cells CEL. For example, the location of the cutting line may be located within the support area DAMA of FIG. 16. The cutting line on which the cutting process is performed may not overlap the ink layer INK′ when viewed on a plane. Accordingly, the ink layer INK′ may protect the internal structure of the cells CEL without being cut.

In the operation S1260, the ink layer INK′ may be removed. The operation S1260 of FIG. 12 may be explained similarly to the operation S740 of FIG. 7 and the operation S1240 of FIG. 12. For example, the ink layer INK′ may be removed in the same method as the support layer DAM of FIG. 16, and the method is not limited to a particular example.

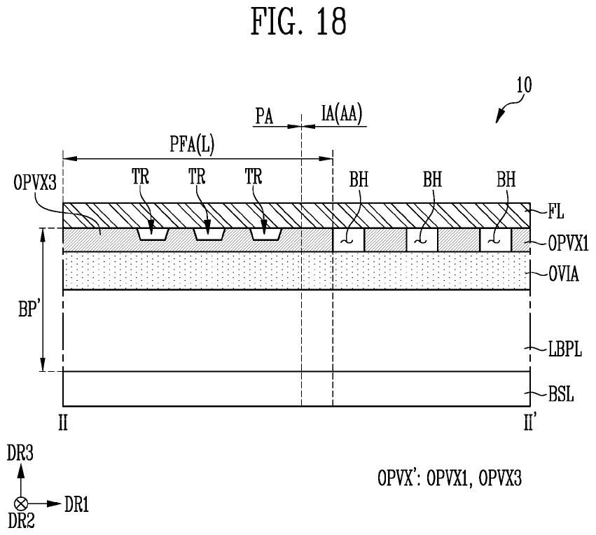

FIG. 18 is a cross-sectional view of the display device taken along the line II-II′ of FIG. 13 after an ink layer is removed in operation S1260 of FIG. 12.

Referring to FIG. 18, after the operation S1260, a film layer FL that protects the backplane structure BP′ may be formed. The film layer FL may cover the outer protective layer OPVX′ and the outer via layer OVIA.

According to some embodiments, the film layer FL may include various materials. For example, the film layer FL may include polyimide.

According to some embodiments, the film layer FL may be a protective member for packaging a laminated structure including the backplane structure BP′. For example, with the film layer FL covering the backplane structure BP′, the laminated structure including the backplane structure BP′ manufactured as described above can be safely transported to subsequent processing equipment.

Thereafter, in the backplane structure BP′ manufactured as described above, the film layer FL may be removed, and a light emitting element layer EML including light emitting elements LE may be provided on the backplane structure BP′. For example, the light emitting elements LE may be located on the backplane structure BP′ to form the active area AA. As described above, the light emitting elements LE may be located in the inner area IA, and the active area AA may be defined.

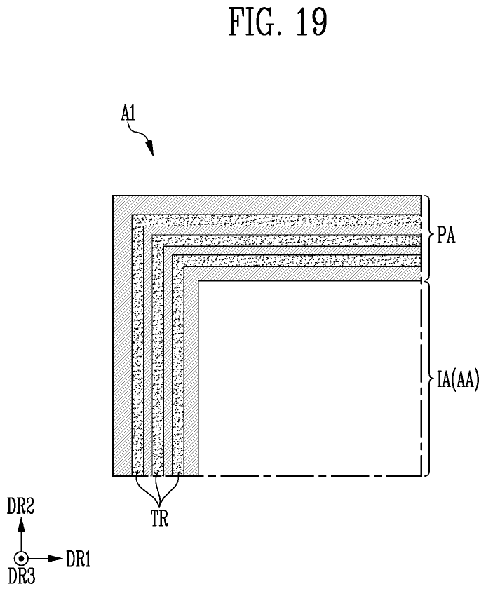

FIG. 19 is a plan view illustrating an example of trenches in an area A1 of FIG. 13 according to some embodiments.

Referring to FIG. 19, the trenches TR may extend along an edge of the active area AA in the peripheral area PA. In some embodiments, the trenches TR may include a plurality of slits. For example, the trenches TR may include a first slit extending in the first direction DR1, a second slit extending in the second direction DR2, and a third slit connecting the first slit and the second slit and having an “L” shape. As described above, the trenches TR of FIG. 16 may be provided as trenches TR having a slit shape.

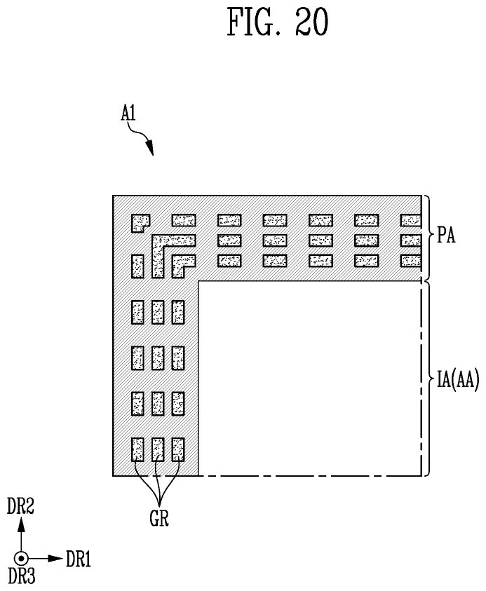

FIG. 20 is a plan view illustrating an example of trenches in the area A1 of FIG. 13 according to some embodiments.

Referring to FIG. 20, a plurality of grooves GR may be arranged along the edge of the active area AA in the peripheral area PA. The grooves GR may include first grooves arranged in the first direction DR1, second grooves arranged in the second direction DR2, and third grooves surround an edge of the ink layer INK′ and having an “L” shape. The trenches TR of FIG. 16 may include the grooves GR.

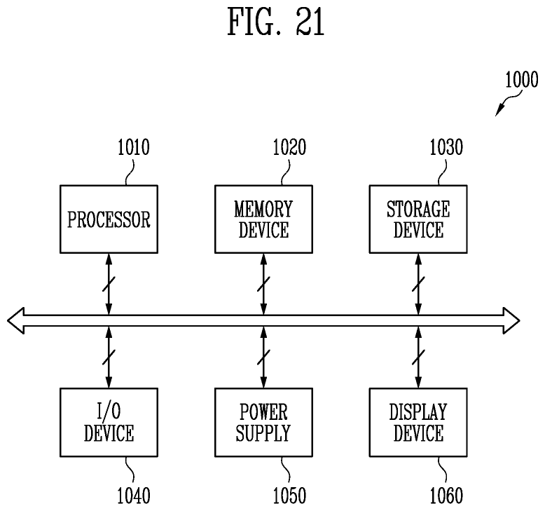

FIG. 21 is a block diagram illustrating an electronic device according to embodiments of the present invention.

Referring to FIG. 21, an electronic device 1000 may include a processor 1010, a memory device 1020, a storage device 1030, an input/output device 1040, a power supply 1050, and a display device 1060. In this case, the display device 1060 may be the display device 10 of FIG. 1. Also, the electronic device 1000 may further include several ports for communicating with video cards, sound cards, memory cards, USB devices, etc. or with other systems.

The electronic device 1000 may be implemented as a mobile phone, a video phone, a smart pad, a smart watch, a vehicle navigation, a computer monitor, a laptop, a head mounted display device, or the like.

The processor 1010 may perform specific calculations or tasks. According to some embodiments, the processor 1010 may be a microprocessor, a central processing unit, an application processor, or the like. The processor 1010 may be connected to other components through an address bus, a control bus, a data bus, or the like. According to some embodiments, the processor 1010 may also be connected to an expansion bus such as a peripheral component interconnect (PCI) bus.

The memory device 1020 may store data necessary for an operation of the electronic device 1000. For example, the memory device 1020 may include a non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or a volatile memory device such as a dynamic random access memory (DRAM) device, a static random access memory (SRAM) device, and a mobile DRAM device.

The storage device 1030 may include a solid state drive (SSD), a hard disk drive (HDD), a CD-ROM, or the like.

The input/output device 1040 may include input means such as a keyboard, a keypad, a touch pad, a touch screen, and a mouse, and output means such as a speaker and a printer. According to some embodiments, the display device 1060 may be included in the input/output device 1040.

The power supply 1050 may supply power sources necessary for an operation of the electronic device 1000. For example, the power supply 1050 may be a power management integrated circuit (PMIC).

The display device 1060 may display an image corresponding to visual information of the electronic device 1000. In this case, the display device 1060 may be an organic light emitting display device or a quantum dot light emitting display device, but the present disclosure is not limited thereto. The display device 1060 may be connected to other components through the buses or other communication links. The display device 10 of FIG. 1 may be provided as the display device 1060.

According to the embodiments of the present invention, a display device that can be manufactured with relatively improved reliability and a manufacturing method thereof are provided.

Effects according to the embodiments are not limited by the above-described contents, and more various other effects are included in the present specification.

Although specific embodiments and implementations have been described herein, other embodiments and modifications may be derived from the foregoing descriptions. Accordingly, the spirit and scope of embodiments according to the present disclosure is not limited to the foregoing embodiments, but may also be applied to the claims set forth below, various obvious modifications, and equivalents.

What is claimed is:

1. A display device including an active area and a peripheral area adjacent to the active area, comprising:
a base layer; and
a backplane structure including a backplane layer on the base layer, an outer via layer on the backplane layer, and an outer protective layer on the outer via layer,
wherein the outer protective layer includes a first outer protective layer having holes exposing the outer via layer in the active area, and a second outer protective layer having a plurality of trenches recessed toward the outer via layer without exposing the outer via layer in the peripheral area.

2. The display device of claim 1, wherein the second outer protective layer overlaps the peripheral area and the active area.

3. The display device of claim 2, wherein the peripheral area is formed along an edge of the active area.

4. The display device of claim 1, wherein each of the plurality of trenches surrounds at least a portion of the active area.

5. The display device of claim 4, wherein the active area extends in a first direction and a second direction crossing the first direction, and
wherein each of the plurality of trenches includes a first slit extending in the first direction, a second slit extending in the second direction, and a third slit connecting the first and second slits and having an “L” shape.

6. The display device of claim 4, wherein the active area extends in a first direction and a second direction crossing the first direction, and
wherein each of the plurality of trenches includes first grooves arranged in the first direction and second grooves arranged in the second direction crossing the first direction.

7. The display device of claim 1, wherein the backplane structure includes a first backplane structure,
wherein the display device further includes a second backplane structure on the base layer and including a second backplane layer, a lower via layer on the second backplane layer, and a lower protective layer on the lower via layer,
wherein the base layer is between the first backplane structure and the second backplane structure, and
wherein the lower protective layer includes a first lower protective layer having holes exposing the lower via layer in the active area, and a second lower protective layer including trenches recessed toward the lower via layer without exposing the lower via layer in the peripheral area.

8. The display device of claim 7, wherein the outer protective layer and the lower protective layer include an inorganic material, and
wherein the outer via layer and the lower via layer include an organic material.

9. A manufacturing method of a display device, the method comprising:
manufacturing cells each including a backplane structure, each of the cells having an active area and a peripheral area adjacent to the active area;
forming a support layer in the peripheral area on a backplane layer;
forming an ink layer overlapping the active area and contacting the support layer on the backplane layer;
removing the support layer; and
separating the cells,
wherein the backplane structure includes an outer via layer, and
wherein the manufacturing the cells includes:
forming a first outer protective layer on the outer via layer in the active area and having holes exposing the outer via layer; and
forming a second outer protective layer on the outer via layer in the peripheral area and having a plurality of trenches recessed toward the outer via layer without exposing the outer via layer.

10. The manufacturing method of claim 9, wherein the forming the second outer protective layer includes:
forming the plurality of trenches using a halftone mask.

11. The manufacturing method of claim 9, wherein the peripheral area is formed along an edge of the active area, and
wherein the second outer protective layer overlaps the peripheral area and the active area.

12. The manufacturing method of claim 11, wherein the support layer includes protrusions directly on the second outer protective layer and protruding toward the outer via layer to fill the trenches.

13. The manufacturing method of claim 9, wherein a height of the ink layer from an upper surface of the first outer protective layer is lower than a height of the support layer from an upper surface of the second outer protective layer.

14. The manufacturing method of claim 9, wherein the removing the support layer includes:
arranging a fixing member to overlap the ink layer so that the ink layer is not separated from the first outer protective layer.
